(19) United States
(12) Patent Application Publication
(10) Pub. No.: US 2007/0138604 A1
(43) Pub. Date: Jun. 21, 2007

(54) HEAT FIXTURE FOR WIRE BONDING

(75) Inventors: Chih Ming Hung, Kaohsiung City (TW); Tai Lieh Lu, Tainan County (TW)

Correspondence Address: LOWE HAUPTMAN BERNER, LLP, 1700 DIAGONAL ROAD, SUITE 300, ALEXANDRIA, VA, 22314, US

(73) Assignee: ADVANCED SEMICONDUCTOR ENGINEERING INC., KAOHSIUNG (TW)

(21) Appl. No.: 11/534,859

(22) Filed: Sep. 25, 2006

(30) Foreign Application Priority Data
Dec. 19, 2005 (TW) 094145029

(51) Int. Cl. H01L 23/495

(52) U.S. Cl. 257/666

(57) ABSTRACT

A heat fixture is adapted to support a leadframe, and the leadframe includes a die pad and a plurality of leads. The heat fixture includes a fixture body and an isolating element. The fixture body is adapted to support the leads of the leadframe. The isolating element is mounted on the fixture body and adapted to support the die pad of the leadframe, wherein the thermal conductivity of the isolating element is less than that of the fixture body.

### CROSS REFERENCE TO RELATED APPLICATION

This application claims the priority benefit of Taiwan Patent Application Serial Number 094145029, filed Dec. 19, 2005, the full disclosure of which is incorporated herein by reference.

### BACKGROUND OF THE INVENTION

1. Field of the Invention

The present invention generally relates to a heat fixture, and more particularly, to a heat fixture for wire bonding.

2. Description of the Related Art

According to semiconductor packaging processes, a leadframe is generally adapted to support a chip. The material of the leadframe can be conductive metal such as copper (Cu) or copper (Cu) alloy, and a metallic layer which is electroplated on inner leads of the leadframe can be made of material of silver (Ag) or gold (Au) so as to increase the conductivity. Compared with gold, silver is lower in material cost. Thus, the metallic layer electroplated on inner leads of the leadframe is generally made of silver.

Referring to FIGS. 1a and 1b, conventional leadframe 120 includes a plurality of outer leads 122, a plurality of inner leads 124 and a die pad 126. The leadframe 120 further includes a plurality of tie bars 128 for supporting the die pad 126. A metallic layer with silver (Ag) and a metallic layer with tin (Sn) are respectively formed on the inner leads 124 and the outer leads 122 by an electroplating process. Typically, the material of the leadframe 120 mainly includes copper and is doped with other trace metal, and is etched or punched so as to form the final shape of the leadframe 120.

A method for manufacturing a semiconductor package having a leadframe includes the following steps of: providing a leadframe 120 which has a die pad 126, inner leads 124 and outer leads 122; electroplating a layer of silver alloy on the die pad 126 and the inner leads 124 so as to increase the conductivity; electroplating a layer of tin alloy on the outer leads 122 so as to cause the leadframe 120 to have the properties of heatproof and high wettability; adhering a chip 110 on the die pad 126, wherein the chip 110 is electrically connected to the inner leads 124 by a wire bonding process, i.e. using a plurality of bonding wires 116 (e.g. golden wires); packaging the chip 110, the die pad 126 and the inner leads 124 by a encapsulant 130; and punching the outer leads 122 so as form a single semiconductor package 100, shown in FIG. 2.

Referring to FIG. 3, during the above-mentioned wire bonding process, the leadframe 120 provided with the chip 110 is generally put on a heat block 200 having a cavity 202. The die pad 126 of the leadframe 120 is put in the cavity 202 of the heat block 200, whereby the heat block 200 can completely supports the die pad 126, the inner leads 124 and the outer leads 122 of the leadframe 120. If the temperature of the heat block 200 is as high as possible (e.g. 200 degrees centigrade), then the temperature of the inner leads 124 is increased, and the eutectoid effect is increased when the bonding wires 116 are soldered, whereby the bonding wires 116 are easily connected to the inner leads 124.

Since the heat block 200 is integrally formed, when the inner leads 124 are heated, the die pad 126 is heated simultaneously. However, if the temperature of the bottom surface 127 of the die pad 126 exceeds about 180˜200 degrees centigrade, the die pad 126 might be oxidized. The oxidization of the die pad 126 will cause the packaged encapsulant 130 to be separated from the bottom surface 127 of the die pad 126. Furthermore, the temperature of the bottom surface 127 of the die pad 126 must be limited to a predetermined value being less than about 180˜200 degrees centigrade, and thus the temperature of the heat block 200 is merely increased to be 200 degrees centigrade, so as to restrict great eutectoid effect when the bonding wires 116 are soldered.

Accordingly, there exists a need for a heat fixture for wire bonding, wherein the heat fixture is capable of solving the above-mentioned problems.

### SUMMARY OF THE INVENTION

It is an object of the present invention to provide a heat fixture for wire bonding, wherein the heat fixture is adapted to simultaneously heat a die pad and a plurality of leads of a leadframe. While the leads are heated to a predetermined temperature, the die pad will not be simultaneously heated to the same predetermined temperature.

In order to achieve the foregoing object, the present invention provides a heat fixture adapted to support a leadframe, wherein the leadframe includes a die pad and a plurality of leads. The heat fixture includes a fixture body and an isolating element. The fixture body is adapted to support the leads of the leadframe. The isolating element is mounted on the fixture body and adapted to support the die pad of the leadframe, wherein the thermal conductivity of the isolating element is less than that of the fixture body.

According to the heat fixture of the present invention, the fixture body and the isolating element are not integrally formed (i.e., the thermal conductivity of the isolating element is less than that of the fixture body), and thus while the inner leads are heated to a predetermined temperature, the die pad will not be simultaneously heated to the same predetermined temperature. Although the temperature of the bottom surface of the die pad must be restricted less than about 180 degrees centigrade, the temperature T1 of the fixture body can be still increased to be more than about 200 degrees centigrade, so as to increase great eutectoid effect when the bonding wires are soldered.

The foregoing, as well as additional objects, features and advantages of the invention will be more apparent from the following detailed description, which proceeds with reference to the accompanying drawings.

### BRIEF DESCRIPTION OF THE DRAWINGS

FIGS. 1a and 1b are sectional and plan schematic views of a leadframe in the prior art.

FIG. 2 is a sectional schematic view of a semiconductor package including a leadframe in the prior art.

FIG. 3 is a sectional schematic view of a wire bonding process in the prior art.

FIG. 4 is a sectional schematic view showing that a heat fixture according to an embodiment of the present invention supports a leadframe and a chip.

FIGS. 5a and 5b are sectional schematic views showing that disassembly and assembly of a heat fixture according to an embodiment of the present invention.

FIGS. 6a and 6b are sectional schematic views showing that disassembly and assembly of a heat fixture according to an alternative embodiment of the present invention.

FIGS. 7a and 7b are sectional schematic views showing that disassembly and assembly of a heat fixture according to another alternative embodiment of the present invention.

FIGS. 8a and 8b are plan and sectional schematic views of an isolating element of the present invention.

FIG. 9 is a sectional schematic view of a wire bonding process according to an embodiment of the present invention.

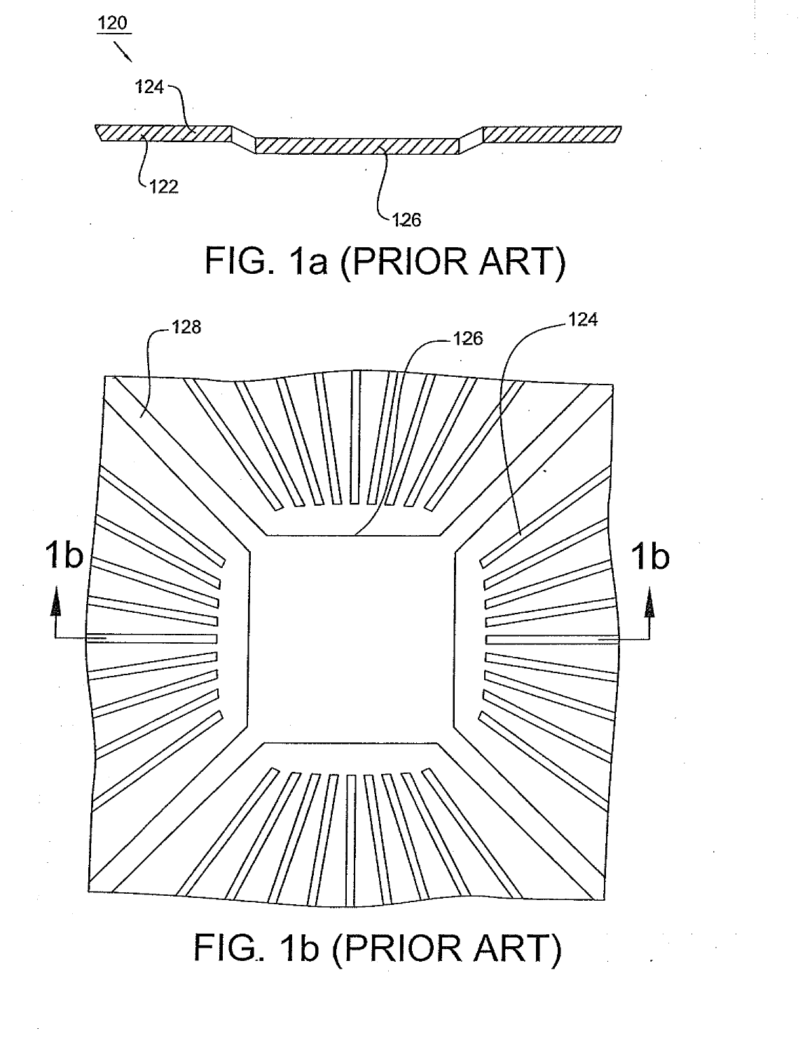

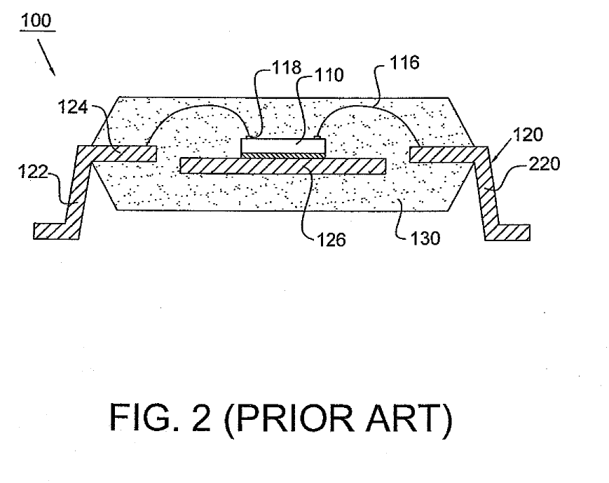

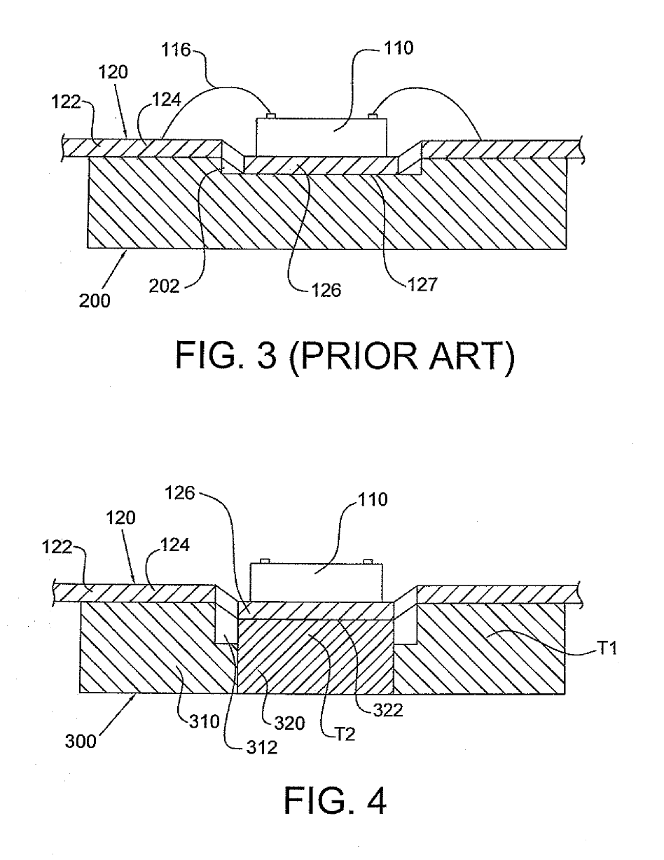

### DETAILED DESCRIPTION OF THE PREFERRED EMBODIMENT

Referring to FIG. 4, it depicts a heat fixture 300 for wire bonding according to an embodiment of the present invention. The heat fixture 300 is adapted to support a leadframe 120 and a chip 110. The heat fixture 300 includes a fixture body 310 and an isolating element 320, and the fixture body 310 defines a cavity 312. The isolating element 320 is mounted on the fixture body 310 and is preferably received in the cavity 312. Thermal conductivity of the isolating element 320 is less than that of the fixture body 310. The fixture body 310 can be a heat block made of metallic material, and the fixture body 310 is made of material with low thermal conductivity (i.e. high thermal resistibility), such as Teflon or plastic steel. Generally, the thermal conductivity of the isolating element 320 is substantially less than 10 BTU.in/hr.ft².° F. Preferably, the thermal conductivity of the isolating element 320 is substantially between 1 and 5 BTU.in/hr. ft².° F.

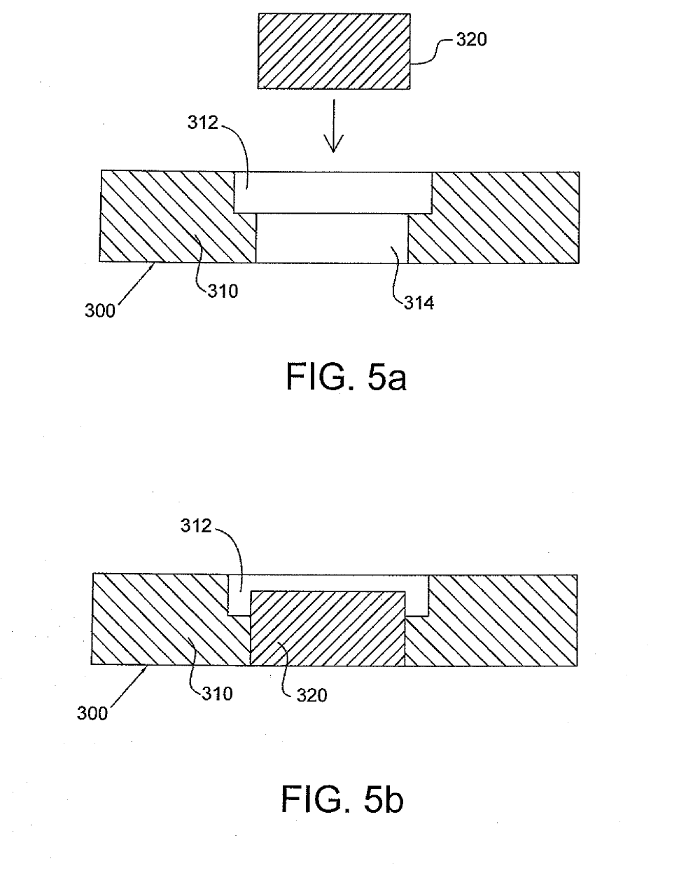

Referring to FIGS. 5a and 5b, the fixture body 310 of the heat fixture 300 in the embodiment can further define a through opening 314, which is located under the cavity 312 and communicated with the cavity 312. The isolating element 320 is mounted in the through opening 314 and extended into the cavity 312.

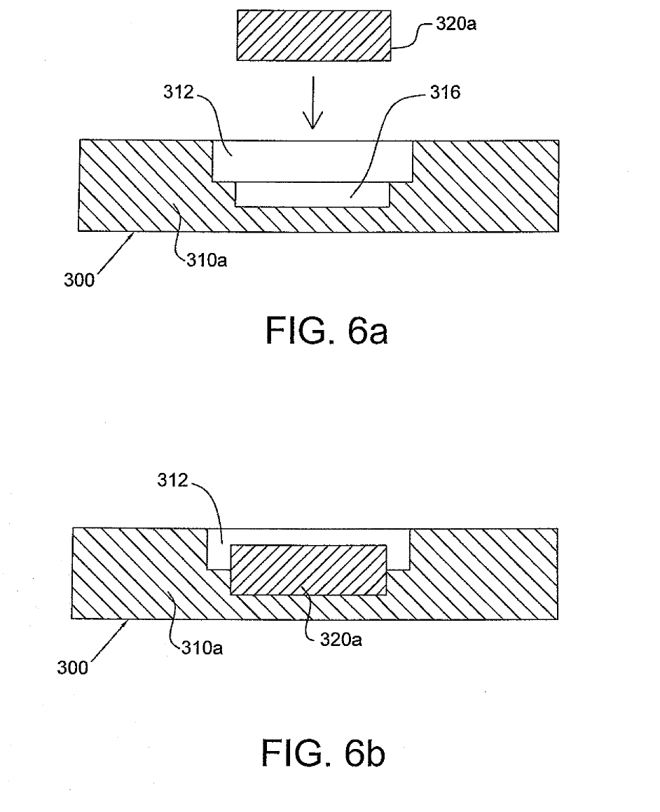

Referring to FIGS. 6a and 6b, the fixture body 310a of the heat fixture 300 according to an alternative embodiment can further define an indentation 316, which is located under the cavity 312 and communicated with the cavity 312. The isolating element 320a is mounted in the indentation 316 and extended into the cavity 312.

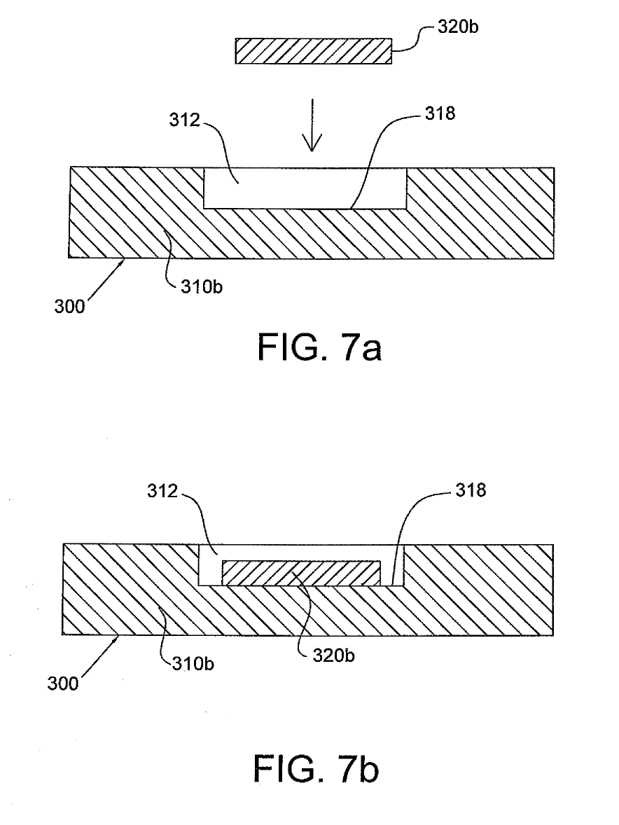

Referring to FIGS. 7a and 7b, the cavity 312 of the fixture body 310b of the heat fixture 300 according to another alternative embodiment can have a surface 318. The isolating element 320b is mounted on the surface 318 of the cavity 312.

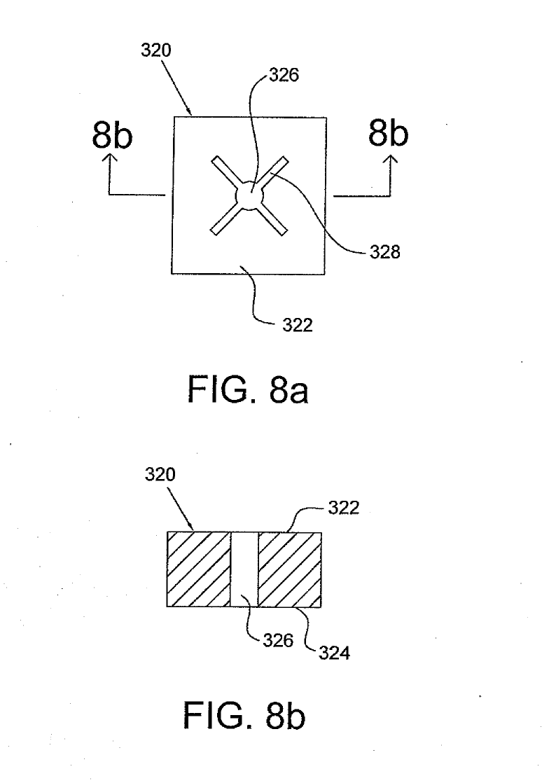

Referring to FIGS. 8a and 8b, the isolating element 320 in the embodiment has an upper surface 322 and a lower surface 324 and includes a through hole 326 and a plurality of grooves 328. The through hole 326 is connected to the upper surface 322 and the lower surface 324. The grooves are located in the upper surface 322, and are communicated with the through hole 326. The through hole 326 is connected to an external vacuum source (not shown), whereby the upper surface 322 of the isolating element 320 has a vacuum attraction so as to attract the leadframe 120 and temporarily mount the leadframe 120.

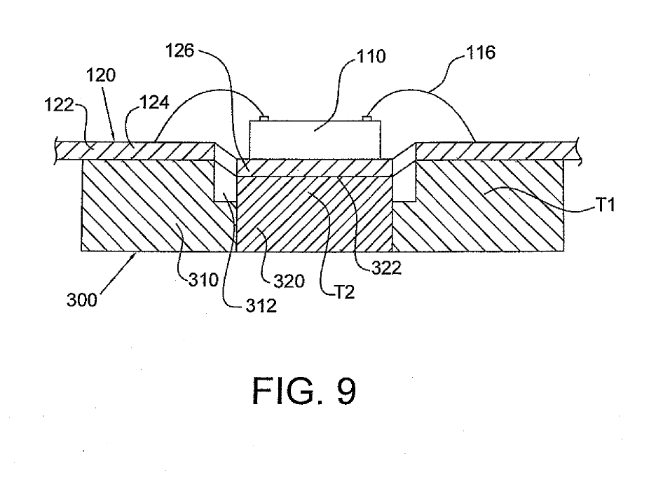

Referring to FIG. 9, the cavity 312 of the fixture body 310 is adapted to accommodate the die pad 126 of the leadframe 120, whereby the fixture body 310 supports the inner leads 124 and the outer leads 122 of the leadframe 120, and the upper surface 322 of the isolating element 320 supports the die pad 126 of the leadframe 120. If the temperature T1 of the fixture body 310 is as high as possible (e.g. the temperature is substantially higher than 200 degrees centigrade, and preferably the temperature is about 230 degrees centigrade), then the temperature of the inner leads 124 is increased, and the eutectoid effect is increased when the bonding wires 116 are soldered, whereby the bonding wires 116 are easily connected to the inner leads 124.

According to the heat fixture of the present invention, the fixture body and the isolating element are not integrally formed (i.e., the thermal conductivity of the isolating element is less than that of the fixture body), and thus while the inner leads are heated to a predetermined temperature, the die pad cannot be simultaneously heated to the same predetermined temperature.

For first example, if the temperature T1 of the fixture body is increased to be about 200 degrees centigrade when the heat fixture is heated, then the temperature of the bottom surface of the die pad and the temperature T2 of the isolating element in the embodiment cannot be more than about 180 degrees centigrade by selecting the thermal conductivity of the isolating element being less than that of the fixture body. Thus, the die pad will not be oxidized, and the packaged encapsulant will not be separated from the bottom surface of the die pad, wherein the temperature difference (T1-T2) is substantially more than 20 degrees centigrade. For second example, if the temperature T1 of the fixture body is increased to about 230 degrees centigrade when the heat fixture is heated, then the temperature of the bottom surface of the die pad and the temperature T2 of the isolating element in the embodiment does not exceed about 180 degrees centigrade by selecting low thermal conductivity of the isolating element. Thus, the die pad will not be oxidized, and the packaged encapsulant will not be separated from the bottom surface of the die pad, wherein the temperature difference (T1-T2) is substantially more than 50 degrees centigrade. For third example, the temperature difference (T1-T2) can be substantially more than 80 degrees centigrade by selecting extremely low thermal conductivity of the isolating element.

As described above, although the temperature of the bottom surface of the die pad must be restricted less than about 180 degrees centigrade, the temperature T1 of the fixture body can be still increased to be more than about 200 degrees centigrade, so as to increase great eutectoid effect when the bonding wires are soldered.

Although the invention has been explained in relation to its preferred embodiment, it is not used to limit the invention. It is to be understood that many other possible modifications and variations can be made by those skilled in the art without departing from the spirit and scope of the invention as hereinafter claimed.

What is claimed is:

1. A heat fixture adapted to support a leadframe, the leadframe including a die pad and a plurality of leads, the heat fixture comprising:
a fixture body adapted to support the leads of the leadframe, the fixture body having a first thermal conductivity; and
an isolating element mounted on the fixture body and adapted to support the die pad of the leadframe, the isolating element having a second thermal conductivity, wherein the second thermal conductivity is less than the first thermal conductivity.

2. The heat fixture as claimed in claim 1, wherein the second thermal conductivity of the isolating element is substantially less than 10 BTU.in/hr.ft².° F.

3. The heat fixture as claimed in claim 1, wherein the second thermal conductivity of the isolating element is substantially between 1 and 5 BTU.in/hr. ft².° F.

4. The heat fixture as claimed in claim 1, wherein the fixture body is made of Teflon or plastic steel.

5. The heat fixture as claimed in claim 1, wherein the fixture body defines a cavity adapted to accommodate the die pad, and the isolating element is received in the cavity.

6. The heat fixture as claimed in claim 5, wherein the fixture body further defines a through opening located under the cavity and communicated with the cavity, and the isolating element is mounted in the through opening and extended into the cavity.

7. The heat fixture as claimed in claim 5, wherein the fixture body further defines an indentation located under the cavity and communicated with the cavity, and the isolating element is mounted in the indentation and extended into the cavity.

8. The heat fixture as claimed in claim 5, wherein the cavity has a surface, and the isolating element is mounted on the surface of the cavity.

9. The heat fixture as claimed in claim 1, wherein the isolating element has an upper surface and a lower surface and includes a through hole and a plurality of grooves, the through hole is connected to the upper surface and the lower surface, the grooves are located in the upper surface, and the grooves are communicated with the through hole.

10. The heat fixture as claimed in claim 1, wherein the temperature of the fixture body is substantially higher than 200 degrees centigrade.

11. The heat fixture as claimed in claim 1, wherein the temperature of the fixture body is about 230 degrees centigrade.

12. The heat fixture as claimed in claim 1, wherein the temperature of the isolating element is substantially less than 180 degrees centigrade.

13. The heat fixture as claimed in claim 1, wherein the temperature difference between the temperatures of the fixture body and the isolating element is substantially more than 20 degrees centigrade.

14. The heat fixture as claimed in claim 1, wherein the temperature difference between the temperatures of the fixture body and the isolating element is between about 20 degrees centigrade and 80 degrees centigrade.

15. The heat fixture as claimed in claim 1, wherein the fixture body is a heat block made of metallic material.
